(19) United States
(12) Patent Application Publication
(10) Pub. No.: US 2022/0006424 A1
(43) Pub. Date: Jan. 6, 2022

(54) POWER OPTIMIZATION OF MULTIPLE FACES OF A SOLAR POWER GENERATION APPARATUS

(71) Applicant: SOLAR EARTH TECHNOLOGIES LTD., Vancouver (CA)

(72) Inventors: Michael Brian WHITWICK, Surrey (CA); Oliver ZIMMERMANN, Bowen Island (CA); Christopher MCCAHON, Delta (CA); Meng WANG, Vancouver (CA)

(21) Appl. No.: 17/436,014

(22) PCT Filed: Mar. 4, 2020
(86) PCT No.: PCT/CA2020/050289

§ 371 Date: Sep. 2, 2021

Related U.S. Application Data
(60) Provisional application No. 62/813,524, filed on Mar. 4, 2019.

(51) Int. Cl. H02S 40/30; H02S 20/00

(52) U.S. Cl. CPC H02S 40/30; H02S 40/22; H02S 20/00

(57) ABSTRACT

There are provided three-dimensional photovoltaic structures and a power optimizer for a photovoltaic power generation apparatus. The photovoltaic structure may include two or more photovoltaic material face sets including one or more photovoltaic material faces with at least in part in different orientations to each other. In embodiments, each photovoltaic material face may be operatively coupled to power optimizer, for example maximum power point tracking (MPPT) electronics, enabling independent power optimization of the power output of each face.

### CROSS REFERENCE TO RELATED APPLICATIONS

This application claims the benefit of priority to U.S. Patent Application Ser. No. 62/813,524 entitled “Power Optimization of Multiple Faces of a Solar Power Generation Apparatus” filed Mar. 4, 2019, which is hereby incorporated by reference in its entirety.

### FIELD OF THE INVENTION

The present invention pertains to the field of photovoltaic power generation and in particular to three-dimensional photovoltaic structures and power optimization for power generation apparatuses.

### BACKGROUND

Performance of many photovoltaic power generation apparatuses is often affected by shading on the photovoltaic device. For example, the overall power output of a photovoltaic power generation apparatus may be diminished by shading on solar cells (e.g. solar panels or modules). The detrimental effect can be considerable even upon minor shading on the solar cells, panels or other modules having a large effect on power generation. Thus, it is apparent, without correction of the power generation apparatus, performance of such devices is limited by the shade on solar cells.

Generally speaking, a typical solar cell of a photovoltaic power generation apparatus uses a p-n junction to generate an electric field for photo-generated carrier separation. The separation of the charge carriers will produce a non-uniform distribution of charged particles. The non-uniformly distributed charged particles will create the electric field for carrier transport. The carriers will be transported in the opposite direction to the p-n junction (e.g. away from the p-n junction). Without light for photogeneration of charge carriers, the p-n junction, in effect, is just a diode with low resistance in a reverse direction of the photogeneration current. Thus, during power generation, the performance of a photovoltaic power generation apparatus can be diminished due to naturally occurring shading such as shade due to debris, leaves or clouds.

Furthermore, for similar reasons, the overall energy generated by a photovoltaic power generation apparatus can also be limited by other local factors such as weather of the region in which the photovoltaic power generation apparatus is placed or the structure of the photovoltaic power generation apparatus.

To resolve the above issue, there have been attempts to develop photovoltaic structures, devices and/or cells with improved solar cell energy conversion efficiencies. One of such attempts includes introduction of three-dimensional structures/geometries in photovoltaic power generation apparatuses. In some photovoltaic power generation apparatuses, three-dimensional structures were nominally added to two-dimensional solar cells in order to reduce light reflection losses and improve light capture. For example, three-dimensional structures can be more productive with respect to capturing sunlight over the course of the day. Such a photovoltaic power generation apparatus may be less affected by shading of the photovoltaic materials. This is particularly relevant for three-dimensional structures in larger scale with dimensions greater than typical charge carrier diffusion lengths. However, while said structures are obtainable with recent advances of nanotechnology, there are still unresolved concerns including high manufacturing costs.

WO2017185188A1 discloses three-dimensional photovoltaic structures and a power generation apparatus comprising same. The photovoltaic structure comprises a light transmitting solid optical core having a longitudinal axis, a top end, a bottom end and one or more side walls, wherein the top end has an exposed outer surface to receive light. A photovoltaic layer surrounds at least a portion of one or more of the side walls of the optical core and an optical cladding layer surrounds the photovoltaic layer. However, this publication does not account for configurations of the three-dimensional photovoltaic structures in which shading of the photovoltaic structures can limit solar energy conversion rates.

Thus, there is a need for photovoltaic power generator structures/solar cells which can exhibit an improved conversion rate from solar radiation to electric power that is not subject to one or more limitations of the prior art.

This background information is provided to reveal information believed by the applicant to be of possible relevance to the present invention. No admission is necessarily intended, nor should be construed, that any of the preceding information constitutes prior art against the present invention.

### SUMMARY

An object of embodiments of the present invention is to provide power optimization of multiple faces of a solar power generation apparatus. According to an aspect of the present invention there are provided three-dimensional photovoltaic structures with local power optimization in a power generation apparatus. In accordance with an aspect of the present invention, there is provided a photovoltaic power generation apparatus including one or more three-dimensional photovoltaic structures generating electrical power, each photovoltaic structure including two or more of photovoltaic material face sets. Each photovoltaic material face set includes one or more photovoltaic material faces, a cladding layer disposed on the one or more photovoltaic material faces and a substrate layer upon which the one or more photovoltaic material faces are disposed. The two or more photovoltaic material face sets are oriented at angles at least in part different from each other. The apparatus further includes one or more power optimizers, the one or more power optimizers operatively connected to the two or more of photovoltaic material face sets, wherein operation of each of the two or more photovoltaic material face sets are independently controlled by the one or more power optimizers.

According to another aspect of the present invention, there is provided a three-dimensional photovoltaic structure generating electrical power. The structure includes two or more of photovoltaic material face sets, each photovoltaic material face set including one or more photovoltaic material faces oriented in a single direction, each photovoltaic material face being operatively connected to a power optimizer. Each photovoltaic material face further includes a cladding layer disposed on the one or more photovoltaic material faces and a substrate layer upon which the one or more photovoltaic material faces are disposed. Each of the two or more photovoltaic material face sets are oriented at angles at least in part different from each other.

In some embodiments, the one or more power optimizers are configured as an electronic component including a processor and machine executable instructions which when executed by the processor perform power optimization. In some embodiments, the one or more power optimizers are configured as integrated circuits. In some embodiments, the one or more power optimizers are configured to perform optimization using one or more of: maximum power point tracking, a variable inductor, curve fitting, incremental resistance, incremental conductance, parasitic capacitance, forced oscillation, ripple correlation, current sweep and fuzzy logic optimization.

In some embodiments, the one or more photovoltaic material faces associated with a first photovoltaic material face set are oriented in a first direction and the one or more photovoltaic material faces associated with a second photovoltaic material face set are oriented in a second direction, the first direction different from the second direction. In some embodiments, a first power optimizer is operatively coupled to the one or more photovoltaic material faces associated with a first photovoltaic material face set and a second power optimizer is operatively coupled to the one or more photovoltaic material faces associated with the second photovoltaic material face set. In some embodiments, the first power optimizer and the second power optimizer are independently operative.

In some embodiments, the one or more power optimizers are operatively connected to supplementary micro-inverter configured to provide additional power optimization. In some embodiments, the one or more power optimizers are operatively connected to one or more of a DC-to-DC converter, a DC-to-AC converter, a battery storage system, a power grid and a load.

In some embodiments, at least one of the one or more photovoltaic material faces are curvilinear.

Embodiments have been described above in conjunction with aspects of the present invention upon which they can be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

### BRIEF DESCRIPTION OF THE FIGURES

Further features and advantages of the present invention will become apparent from the following detailed description, taken in combination with the appended drawings, in which:

FIG. 1 illustrates, in a side view, a photovoltaic power generation apparatus with two photovoltaic material faces, in accordance with embodiments of the present invention.

FIG. 2 illustrates a power output from a three-dimensional photovoltaic device having two photovoltaic faces in different orientations, wherein the power output is optimized based on output from the full device, or optimized on an individual photovoltaic face basis, in accordance with embodiments of the present invention.

FIG. 3 illustrates, in a side view, a photovoltaic power generation apparatus with four photovoltaic material faces, in accordance with embodiments of the present invention.

FIGS. 4A and 4B illustrate, in a perspective view and a top view, a photovoltaic power generation apparatus with four photovoltaic material faces in a shape of reversed pyramid, in accordance with embodiments of the present invention.

FIGS. 4C and 4D illustrate, in a perspective view and a top view, a photovoltaic power generation apparatus with four photovoltaic material faces wherein two photovoltaic material faces share one power optimizer, in accordance with embodiments of the present invention.

FIGS. 5A and 5B illustrate, in a perspective view and a top view, a photovoltaic power generation apparatus with two non-planar photovoltaic material faces shaped in a reversed cone, in accordance with embodiments of the present invention.

FIG. 6 illustrates, in a side view, a photovoltaic power generation system with two photovoltaic material face sets forming a three-dimensional corrugated structure, in accordance with embodiments of the present invention.

It will be noted that throughout the appended drawings, like features are identified by like reference numerals.

### DETAILED DESCRIPTION

As used herein, the term “about” should be read as including variation from the nominal value, for example, a +/−10% variation from the nominal value. It is to be understood that such a variation is always included in a given value provided herein, whether or not it is specifically referred to.

As used herein, the term “geometric prism” refers to a three-dimensional shape or geometry having top and bottom faces connected by flat or curved sidewalls. A geometric prism may be also referred to herein as a microprism, and include cylinders, cubes, cuboids, triangular prisms, rectangular prisms, pentagonal prisms, hexagonal prisms, octagonal prisms, and the like. In some embodiments, the top and bottom faces are placed in parallel. In some embodiments, the top and bottom faces are equal or similar in size and shape. However, it should be also envisioned that some geometric prisms may have differently sized and/or shaped top and bottom faces, for example as is seen in truncated cones, frustums or frustroconical shapes.

As used herein, the term “conical shape” refers to a three-dimensional shape or geometry tapering from a top face to a bottom face or from a bottom face to a top face. In some embodiments, one of the top and bottom faces may be a point or a vertex. In some embodiments, both top and bottom faces have a non zero surface area while either the top face is smaller than the bottom face or vice versa, wherein the lateral surfaces or sidewalls is not parallel. The conical shaped structures can have a cross sectional shape of a circle, triangular, square, pentagon, hexagon, or other shape as would be readily understood. Example conical shapes can include cones, pyramids, and the like.

Unless defined otherwise, all technical and scientific terms used herein have the same meaning as commonly understood by one of ordinary skill in the art to which this invention belongs.

It has been realised that the negative effect of shading can be mitigated by installing by-pass diodes on individual solar cells, sets of plural solar cells or solar cell modules. This method can partially prevent shaded solar cell or sets of solar cells or solar cell modules from being damaged during power generation until the shade that impacts the solar cells has alleviated. In addition, it has also been realised that power optimization can used to mitigate the negative effects of shading of the solar cells. Micro-inverters or power optimizers using maximum power point tracking (MPPT) hardware/software/firmware can be used to substantially match the output load impedance to the power generated from solar cell(s) which varies by the amount of light.

The present invention provides a photovoltaic power generation apparatus which includes, but not limited to, optical elements, structural elements and reflective elements that can provide a means for mitigation of the affect of shading on the operational characteristics of the photovoltaic power generation apparatus. According to some embodiments, the photovoltaic power generation apparatus comprises three-dimensional photovoltaic structures and power optimizers. In some embodiments, the photovoltaic power generation apparatus comprises one or more three-dimensional photovoltaic structures. In some embodiments, the photovoltaic power generation apparatus comprises multiple three-dimensional photovoltaic structures, each of which may be structurally and/or functionally equivalent to each other. For example, similar photovoltaic structures may be repeatedly placed within one photovoltaic power generation apparatus. The three-dimensional photovoltaic structures may be shaped in three-dimensional geometry, such as geometric prisms or conical shapes.

According to embodiments, the three-dimensional photovoltaic structures comprise two or more sets of photovoltaic material faces. In some embodiments, each photovoltaic material face set can be defined by a shared orientation to a reference, such as the power generation mounting plane, and a shared power optimizer. For example, each photovoltaic material face in the same photovoltaic material face set may be configured to have substantially the same orientation or oriented in the same direction, relative to an intended reference plane. In some embodiments of the invention these planes can be tuned for a specific solar incident angle. In some embodiments, two or more photovoltaic material faces in the same photovoltaic material face set can be coupled to the same power optimizer. In some embodiments, photovoltaic material faces in different photovoltaic material face sets can be coupled to the same power optimizer thereby sharing the power optimizer.

According to embodiments, each set of the photovoltaic material faces comprise one or more photovoltaic material elements. The photovoltaic material faces may be optimized in power generation for three-dimensional photovoltaic structures. Each photovoltaic material element may be configured such that each set of photovoltaic faces is wired in series, such that the overall voltage is increased, and each photovoltaic element of the face aligned along the same direction relative to the overall unit. One or more of the photovoltaic material faces may be combined together to form a three-dimensional photovoltaic structure. A three-dimensional photovoltaic structure can be configured in the shape of a geometric prism, which may provide effective power generation. In some embodiments, the one or more photovoltaic material faces may be coupled to power optimizers such as maximum power point tracking (MPPT) electronics, charge controller, or inverter electronics, providing efficient power generation over a wide range of solar incident angles and robustness to local shading.

According to embodiments, photovoltaic conversion may occur at the photovoltaic material faces, wherein each material face can be composed of solar cells, that may include one or more types of solar cell. Embodiments may include one or more available solar cell material technologies, which may include amorphous silicon, silicon, biohybrid, cadmium telluride, concentrated, copper indium gallium selenide, crystalline silicon, dye-sensitized, gallium arsenide germanium, hybrid, luminescent solar concentrator, tandem, monocrystalline silicon, multi-junction, nanocrystal, organic, perovskite, photoelectrochemical, plasmonic, polycrystalline, quantum dot, solid-state, thin-film, heterojunction with intrinsic thin-layer, interdigitated back contacted, rectenna, nanotube, graphene, or Schottky solar cells. It will be readily understood that these examples are to be considered as non-limiting potential solar cell technologies. One or more properties of the solar cells may be selected and configured to carry out the most effective power generation by the photovoltaic power generation apparatus. The solar cell properties may include reflectivity, optical absorption and recombination rate. In some embodiments, one or more solar cells may be disposed as a layer, and this photovoltaic material face may also be referred to as a photovoltaic layer.

According to embodiments, a photovoltaic layer may comprise an upper metallic layer, one or more conductive layers, and a lower metallic layer. The upper metallic layer may be proximate to a cladding layer and disposed on the one or more conductive layers. The one or more conductive layers may be disposed on the lower metallic layer. The lower metallic layer may be proximate to and disposed on the substrate layer.

According to embodiments, the conductive layers can be semi-conductive layers and can be referred to as P-N junction layers. The conductive layers may comprise one or more P-N junctions. The P-N junctions may be configured to generate an electrical voltage in response to photonic bombardment and penetration, in accordance with the photovoltaic effect.

In some embodiments, each semi-conductive layer or P-N junction may be composed of photovoltaic materials to facilitate a wide range of light absorption and charge separation mechanisms. Some examples of photovoltaic materials that can be used for the semi-conductive layer or P-N junction include crystalline silicon (c-Si), monocrystalline silicon, polycrystalline silicon, ribbon silicon, mono-like-multi silicon, cadmium telluride, copper indium gallium selenide, silicon thin film, gallium arsenide thin film, and any combination thereof.

According to embodiments, top ends of the photovoltaic structures, whether they are three-dimensional or not, can be directly exposed to the sunlight thereby enabling the energy conversion. At least one side of the photovoltaic material faces receives and/or captures light (e.g. solar radiation) and the received/captured light can be converted into electrical energy by the photovoltaic power generation apparatus. In some embodiments, to more effectively receive or capture the light, the top end of the photovoltaic structure may be processed differently. For example, the photovoltaic structure may be configured to have a unique geometric shape or may be coated with a thin anti-dust film. Other means for enhancing the light collection or capturing properties of the photovoltaic structure can include one or more of the incorporation of nanostructures, concentration using one or more optical elements including concentrators, reflectors, refractors and the like, active solar tracking and inclusion of anti-reflection coatings on the cells. It will be readily understood that these examples are to be considered as non-limiting for potential means for enhancing the light collection or capturing properties of the photovoltaic structure.

According to embodiments, there are provided power optimizers that are operatively coupled to photovoltaic material faces. In some embodiments, the power optimizer may refer to an external electronic component (e.g. external to the photovoltaic structure) that continually alters the load placed on the photovoltaic structures in order to maximize the overall performance (e.g. power output) of the photovoltaic power generation apparatus. The power optimizer may be useful because of inconsistent performance of the photovoltaic structure. The inconsistency of the performance of the photovoltaic structure may be caused by changes in amount of light input. The power optimizer can be individually coupled to elements designed to control the amount of light input to the photovoltaic structures.

In some embodiments, the power optimizer may take the form of an electronic component that can have firmware/software for performing optimization or can be configured as an integrated circuit. The power optimizer can use one or more power optimization techniques including maximum power point tracking (MPPT). Power optimization techniques can also include using a variable inductor, curve fitting, incremental resistance, incremental conductance, parasitic capacitance, forced oscillation, ripple correlation, current sweep, hill climbing, 3-point weighted technique, fuzzy logic optimization, SC-current relays, DC-link capacitor droop control, state-based techniques, gradient, or look-up table methods. It will be readily understood that these examples are to be considered as non-limiting for potential power optimization techniques. The MPPT technique may be operatively used by or coupled to DC-to-DC (direct current to direct current) boost conversion circuits (e.g. DC-to-DC converter) or DC-to-AC (direct current to alternating current) inversion circuits (e.g. solar micro-inverter) thereby attempting to maximize the energy harvest from the sets of the photovoltaic material faces.

According to embodiments, power generated by the photovoltaic material face sets and optimized by the power optimizer may be a sole source of power for use by one or more electric devices. In some embodiments, power generated by the photovoltaic material face sets and optimized by the power optimizer may be combined with the output of other power sources for use by one or more electric devices. In some embodiments, power generated by the photovoltaic material face sets and optimized by the power optimizer can be used in real-time, stored in batteries, provided as input into the electric grid or used for other purposes as would be considered appropriate and readily understood by a worker skilled in the art.

According to embodiments, there are provided improvements to a photovoltaic power generation apparatus with three-dimensional photovoltaic structures to generate increased power output without for altering the physical or chemical properties of the semiconductor of the photovoltaic material faces, thereby enabling increased power generation during low light scenarios. Some embodiments can minimize detrimental effects of shading on the power generation unit from external factors such as clouds or nearby objects. Similarly, some embodiments can allow for efficient operation of the power generation unit due to reduced light conditions caused by external factors such as overcast conditions, dusk, dawn, rain, light snow, fog, haze, pollution, smoke, ash, dust, or dirt or the like. In some embodiments the three-dimensional structures provide increased photovoltaic surface area in a compact space. The sets of photovoltaic faces can have multiple orientations with respect to a reference plane of the power unit (for example a mounting plane of the photovoltaic faces); thereby enabling collection of light over a wide range incident angles of the light, which is characteristic of low light conditions where scattering and reflection of light due to objects and particles may occur. It is understood that the amount of light on the different sets of photovoltaic faces can vary at one instance and over time, wherein some faces can receive more light than others. As power optimizers have an optimal input range that is typically tuned to normal light conditions, separating the brighter sets of photovoltaic faces from the darker sets of photovoltaic faces can allow improved operation of the power generation unit. In some embodiments, using a local power optimizer operatively coupled to independent photovoltaic material face sets, performance of the photovoltaic structures may be improved up to 300% compared to the performance of the same photovoltaic structures without a local power optimizer. In this manner the power optimizer is capable of dynamic adjustment for shading mitigation based on local operation of the photovoltaic faces associate therewith.

According to embodiments, there are provided improvements to photovoltaic power generation apparatus with three-dimensional photovoltaic structures to generate more power outputs without altering the physical or chemical properties of the semiconductor of the photovoltaic material faces during power generation in normal or high light conditions. In some embodiments the three-dimensional structures provide additional photovoltaic surface area to enable the capture or concentration of light. The sets photovoltaic faces can have multiple orientations with respect to a reference plane of the power unit (such as a mounting plane of the photovoltaic material faces); enabling collection of light over a wide range of incident angles of the light, for example as would occur during natural varying of solar incident angles through the day from dust to dawn. Using a local power optimizer operatively coupled to each photovoltaic material face set allows the tuning of the photovoltaic faces for multiple solar incident angles, thereby enabling a more efficient operation thereof through the day, month, or year. In some embodiments, the tuning has been found to improve the performance of the photovoltaic structures by up to 150% in normal lighting conditions.

According to embodiments, by localizing the operational characteristics of the photovoltaic faces, each of the faces may be substantially independently tuned based on their received light. This tuning may be dynamically performed in order to mitigate fluctuations of photovoltaic face operation over time. For example, where a set of photovoltaic faces includes two photovoltaic faces oriented at different angles relative to each other, each of these faces will be impinged by different levels of light. By dynamically and independent controlling the optimization of the operation and power conversion of each of these photovoltaic faces, improved operation thereof can be achieved, when compared with optimization of the set of photovoltaic faces as a unit. For example, it would be understood that optimization of the set of photovoltaic faces as a unit, may be considered optimization of an “average” of the photovoltaic faces of the set, which may result in sub-optimization of operation and power conversion of the photovoltaic faces.

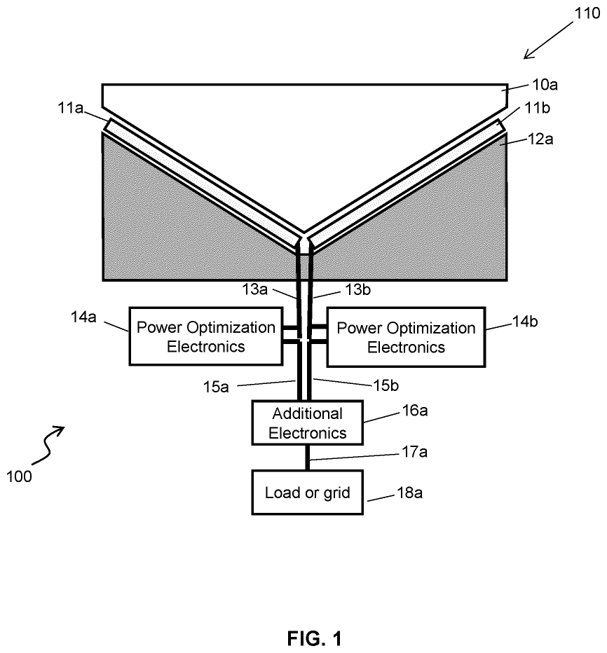

FIG. 1 illustrates, in a side view, a photovoltaic power generation apparatus with two independent photovoltaic material faces, in accordance with embodiments of the present invention. According to embodiments, the photovoltaic power generation apparatus 100 may comprise the power generation photovoltaic structure 110 and the power optimization electronics 14a and 14b (e.g. local power optimizer), and the electronic load/grid 18a. The power generation photovoltaic structure 110 may comprise the photovoltaic material faces 11a and 11b, cladding layer 10a and substrate layer 12a. Each of the photovoltaic material faces 11a and 11b may form separate photovoltaic material face set. In some embodiments, two or more photovoltaic material faces may form one photovoltaic material face set. In some embodiments, the photovoltaic power generation apparatus 100 may further comprise the additional electronic component 16a.

Referring to FIG. 1, each of the photovoltaic material faces 11a and 11b may be operatively connected to independent power optimization electronics 14a and 14b. The photovoltaic material face 11a may be operatively connected to the power optimization electronic (e.g. local power optimizer) 14a via the connecting components 13a; and the photovoltaic material face 11b may be operatively connected to the power optimization electronic (e.g. local power optimizer) 14b via the connecting components 13b. Each of the power optimization electronics 14a and 14b may be operatively connected to the additional electronic component 16a via the connecting components 15a and 15b, respectively. The additional electronic component 16a may be operatively connected to the electronic load/grid 18a via the connecting component 17a.

According to embodiments, the cladding layer 10a may be disposed on the photovoltaic material faces 11a and 11b which may be disposed on the substrate layer 12a. While the cladding layer 10a is proximate to the photovoltaic material faces 11a and 11b, the cladding layer 10a and the photovoltaic material faces 11a and 11b may not be in direct contact with each other and a thin gap may exist therebetween. Similarly, while the substrate layer 12a is proximate to the photovoltaic material faces 11a and 11b, the substrate layer 12a and the photovoltaic material faces 11a and 11b may not be in direct contact with each other and a thin gap may exist therebetween. However, in some embodiments, at least part of the cladding layer 10a may be in direct contact with the photovoltaic material faces 11a and 11b. Similarly, in some embodiments, at least part of the substrate layer 12a may be in direct contact with the photovoltaic material faces 11a and 11b. The substrate layer 12a may provide some space for the connection between the photovoltaic material faces (11a, 11b) and the power optimization electronics (14a, 14b). In some embodiments, at least part of the cladding layer 10a and the substrate layer 12a may be in contact with each other.

According to embodiments, the cladding layer 10a may be configured using a mixture of optical, light trapping, anti-reflection, structural, anti-skid, heat managing, water-sealing and bonding elements. The substrate layer 12a may be configured using a mixture of anti-reflection, light trapping, structural, water-proofing, heat managing, and bonding elements.

The photovoltaic material faces 11a and 11b may be made of photovoltaic materials having light-absorbing characteristics. In some embodiments, the photovoltaic material faces 11a and 11b may be configured to have a single layer of photovoltaic material. In some embodiments, the photovoltaic material faces 11a and 11b may be configured to have multiple layers of photovoltaic material to facilitate a wide range of light absorption and charge separation mechanisms. Some examples of photovoltaic materials that can be used for the photovoltaic material faces include crystalline silicon (c-Si), monocrystalline silicon, polycrystalline silicon, ribbon silicon, mono-like-multi silicon, cadmium telluride, copper indium gallium selenide, silicon thin film, gallium arsenide thin film, or the like or any combination thereof.

According to embodiments, each of the photovoltaic material faces 11a and 11b may be configured to have any orientation, relative to a reference plane, such as the mounting plane of the power generation unit, with angles that are different from each other photovoltaic material face. The multiple photovoltaic material faces may form elements of light management structures or be an optimal mounting configuration for a specific light condition, such as a solar incident angle or to capture ambient scattering. Overall, the photovoltaic material faces 11a and 11b can be configured to optimize the energy production of the unit over the course of a day or year. Also, due to the absence or significantly reduced surface area at the bottom, there may be limited need to have the photovoltaic material faces at the bottom of the three-dimensional photovoltaic structure.

According to embodiments, the local power optimization electronics 14a and 14b may continually alter the load placed on the photovoltaic structures in order to maximize the overall performance (e.g. power output) of the photovoltaic power generation apparatus.

According to embodiments, the additional electronic component 16a may take the energy or power transmitted from the power optimization electronics 14a and 14b. The additional electronic component 16a may combine and/or prepare the energy/power from the power optimization electronics 14a and 14b before transmitting the energy/power to the electronic load 18a. In some embodiments, additional power optimization electronics, such as a supplementary micro-inverter, may be operatively connected to the local power optimization electronics 14a and 14b through the additional electronic component 16a.

According to embodiments, there may be various forms and types available for the additional electronic component 16a. Solar power generation systems commonly have additional electronics to alter the generated power to suite the load for the desired application. In some embodiments, the additional electronic component 16a may be a set of plain electronic wires connected in series or in parallel. In some embodiments, the additional electronic component 16a may be one or more electrical devices such as a DC-to-DC converter, a DC-to-AC inverter, a battery storage system, a power grid, or a direct connection to a load. The additional electronic component 16a may be able to carry or manage DC (direct current) or AC (alternating current) of any voltage, frequency, amperage or wattage.

According to embodiments, the load 18a may be an electrical device that takes and consumes electrical energy produced by the sets of the photovoltaic material faces. The load 18a may be able to take, consume or manage DC or AC of any voltage, frequency, amperage or wattage. In some embodiments, the load 18a may directly consume the energy produced by the photovoltaic material faces. In some embodiments, the load 18a may store the energy into an energy accumulator or battery. In some embodiments, the load 18a may transmit energy to the electrical grid (e.g. offloaded to the electrical grid).

According to embodiments, there may be various forms and types available for the connecting components 13a, 13b, 15a, 15b and 17a. In some embodiments, one or more of the connecting components 13a, 13b, 15a, 15b and 17a may be conventional electrical wires. In some embodiments, one or more of the connecting components 13a, 13b, 15a, 15b and 17a may be a set of transmitter(s) and receiver(s) for wireless power transmission or wireless electricity transmission. As such, the power or electric transmissions via the connecting components 13a, 13b, 15a, 15b or 17a may be wired transmissions, wireless transmissions or combination thereof.

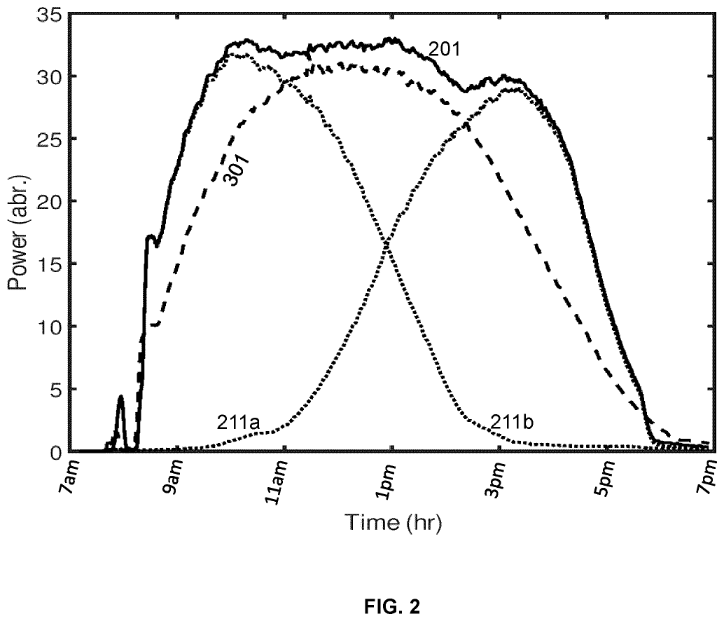

FIG. 2 illustrates a power output from a three-dimensional photovoltaic device having two photovoltaic faces in different orientations, wherein the power output is optimized based on output from the full device, or optimized on an individual photovoltaic face basis in accordance with embodiments of the present invention. The graph illustrates the varying power output as it varies over the course of a day, and in this graph the day is considered to be a day of full sun. Curve 301 illustrates the optimized power output of the three-dimensional photovoltaic device having two photovoltaic faces in different orientations wherein the output power is optimized on the full output of the device, namely the optimization of the output power of both faces together. It is noted that the power substantially maximizes at midday, when both faces are likely fully illuminated. Curve 201 illustrates the optimized power output of the three-dimensional photovoltaic device having two photovoltaic faces in different orientations wherein the output power of each of the photovoltaic faces is optimized independently in accordance with embodiments of the present invention. Curve 211a illustrates the optimized power output of a first photovoltaic face and curve 211b illustrates the optimized power output of a second photovoltaic face. As can been see from the curves 211a and 211b, the optimized power output thereof peaks at different times during the day due to the orientation thereof relative to the changing position of the sun over the course of a day. From FIG. 2 is can be identified that the combination of a three-dimensional structure with independent power optimization of the photovoltaic faces yielded a 1.348 increase in energy generated over the course of a day, when compared with power optimization of the output of both faces together.

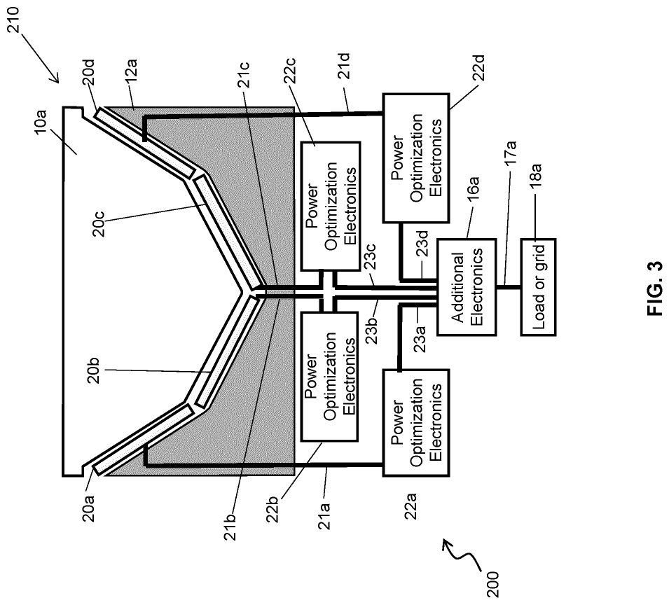

FIG. 3 illustrates, in a side view, a photovoltaic power generation apparatus with four independent photovoltaic material faces, in accordance with embodiments of the present invention. According to embodiments, the photovoltaic power generation apparatus 200 may comprise the power generation photovoltaic structure 210 and the power optimization electronics 22a, 22b, 22c and 22d (e.g. local power optimizer), and the electronic load/grid 18a. Each of the power optimization electronics 22a, 22b, 22c and 22d may be functionally equivalent to the power optimization electronics 14a and 14b in FIG. 1. The power generation photovoltaic structure 210 may comprise the photovoltaic material faces 20a, 20b, 20c and 20d, cladding layer 10a and substrate layer 12a. Each of the photovoltaic material faces 20a, 20b, 20c and 20d may be functionally equivalent to the photovoltaic material faces 11a and 11b in FIG. 1. Each of the photovoltaic material faces 20a, 20b, 20c and 20d may form separate photovoltaic material face set. In some embodiments, two or more photovoltaic material faces may form one photovoltaic material face set. In some embodiments, the photovoltaic power generation apparatus 200 may further comprise the additional electronic component 16a.

Referring to FIG. 3, each of the photovoltaic material faces 20a, 20b, 20c and 20d may be configured in any orientation relative to a reference plane in the power generation unit, such as the mounting plane, with each independent photovoltaic material face at a different angle from other photovoltaic material faces. The photovoltaic material faces 20a, 20b, 20c and 20d may be configured to optimize the photovoltaic energy production. Also, due to the absence of or significantly reduced surface area at the bottom, there may be no need to have the photovoltaic material faces at the bottom of the three-dimensional photovoltaic structure.

Further referring to FIG. 3, each of the photovoltaic material faces 20a, 20b, 20c and 20d may be operatively connected to independent power optimization electronics 22a, 22b, 22c and 22d. The photovoltaic material face 20a may be operatively connected to the power optimization electronic (e.g. local power optimizer) 22a via the connecting components 21a; the photovoltaic material face 20b may be operatively connected to the power optimization electronic (e.g. local power optimizer) 22b via the connecting components 21b; the photovoltaic material face 20c may be operatively connected to the power optimization electronic (e.g. local power optimizer) 22c via the connecting components 21c; and the photovoltaic material face 20d may be operatively connected to the power optimization electronic (e.g. local power optimizer) 22d via the connecting components 21d. Each of the power optimization electronics 22a, 22b, 22c and 22d may be operatively connected to the additional electronic component 16a via the connecting components 23a, 23b, 23c and 23d, respectively. The additional electronic component 16a may be operatively connected to the electronic load/grid 18a via the connecting component 17a.

Further referring to FIG. 3, the cladding layer 10a may be disposed on the photovoltaic material faces 20a, 20b, 20c and 20d which may be disposed on the substrate layer 12a. While the cladding layer 10a is proximate to the photovoltaic material faces 11a and 11b, the cladding layer 10a and the photovoltaic material faces 20a, 20b, 20c and 20d may not be in direct contact with each other and thin gap may exist therebetween. Similarly, while the substrate layer 12a is proximate to the photovoltaic material faces 11a and 11b, the substrate layer 12a and the photovoltaic material faces 20a, 20b, 20c and 20d may not be in direct contact with each other and thin gap may exist therebetween. However, in some embodiments, at least part of the cladding layer 10a may be in direct contact with the photovoltaic material faces 20a, 20b, 20c and 20d. Similarly, in some embodiments, at least part of the substrate layer 12a may be in direct contact with the photovoltaic material faces 20a, 20b, 20c and 20d. The substrate layer 12a may provide some space for the connection between the photovoltaic material faces 20a, 20b, 20c, 20d and the power optimization electronics 22a, 22b, 22c, 22d. In some embodiments, at least part of the cladding layer 10a and the substrate layer 12a may be in contact with each other.

According to embodiments, there may be various forms and types available for the connecting components 21a, 21b, 21c, 21d and 23a, 23b, 23c, 23d. In some embodiments, one or more of the connecting components 21a, 21b, 21c, 21d and 23a, 23b, 23c, 23d may be conventional electrical wires. In some embodiments, one or more of the connecting components 21a, 21b, 21c, 21d and 23a, 23b, 23c, 23d may be a set of transmitter(s) and receiver(s) for wireless power transmission or wireless electricity transmission. As such, the power or electric transmissions via the connecting components 21a, 21b, 21c, 21d and 23a, 23b, 23c, 23d may be wired transmissions, wireless transmissions or combination thereof.

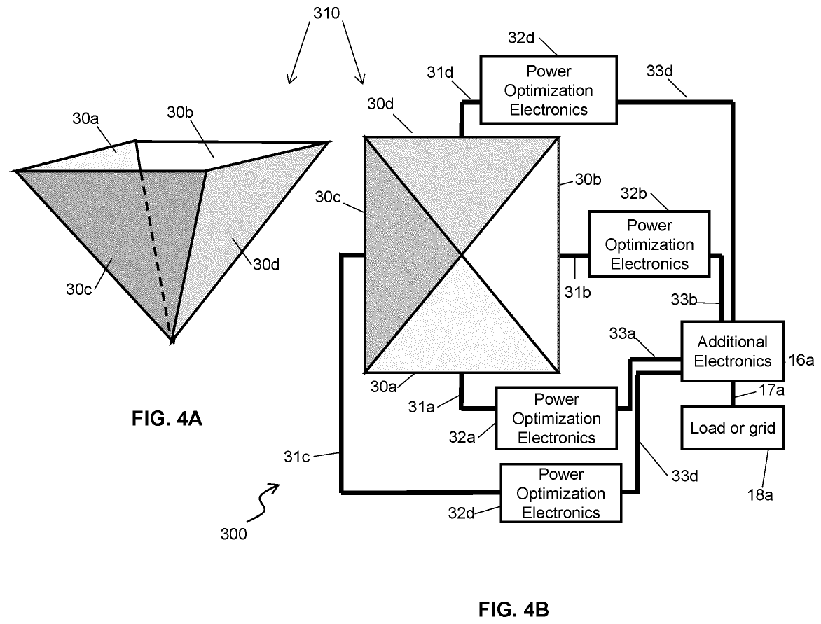

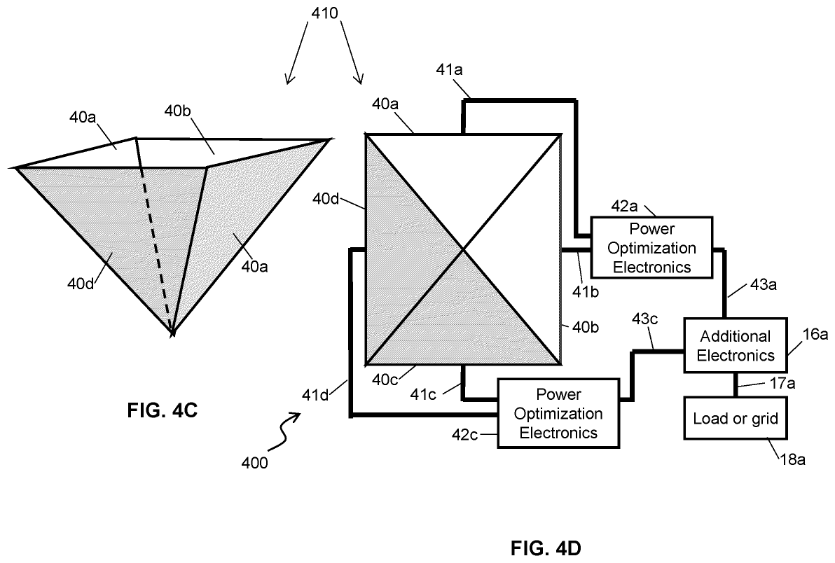

FIGS. 4A and 4B illustrate, in a perspective view and a top view, a photovoltaic power generation apparatus with four independent photovoltaic material faces in a shape of reversed pyramid, in accordance with embodiments of the present invention. According to embodiments, the photovoltaic power generation apparatus 300 may comprise the power generation photovoltaic structure 310 and the power optimization electronics 32a, 32b, 32c and 32d (e.g. local power optimizer), and the electronic load/grid 18a. Each of the power optimization electronics 32a, 32b, 32c and 32d may be functionally equivalent to the power optimization electronics 14a and 14b in FIG. 1. The power generation photovoltaic structure 310 may comprise the photovoltaic material faces 30a, 30b, 30c and 30d. While not shown in FIGS. 4A and 4B, the power generation photovoltaic structure 310 may further comprise cladding layer 10a and substrate layer 12a. Each of the photovoltaic material faces 30a, 30b, 30c and 30d may be functionally equivalent to the photovoltaic material faces 11a and 11b in FIG. 1. Each of the photovoltaic material faces 30a, 30b, 30c and 30d may form separate photovoltaic material face set. In some embodiments, two or more photovoltaic material faces may form one photovoltaic material face set. In some embodiments, the photovoltaic power generation apparatus 300 may further comprise the additional electronic component 16a.

Referring to FIGS. 4A and 4B, each of the photovoltaic material faces 30a, 30b, 30c and 30d may be operatively connected to independent power optimization electronics 32a, 32b, 32c and 32d. The photovoltaic material face 30a may be operatively connected to the power optimization electronic (e.g. local power optimizer) 32a via the connecting components 31a; the photovoltaic material face 30b may be operatively connected to the power optimization electronic (e.g. local power optimizer) 32b via the connecting components 31b; the photovoltaic material face 30c may be operatively connected to the power optimization electronic (e.g. local power optimizer) 32c via the connecting components 31c; and the photovoltaic material face 30d may be operatively connected to the power optimization electronic (e.g. local power optimizer) 32d via the connecting components 31d. Each of the power optimization electronics 32a, 32b, 32c and 32d may be operatively connected to the additional electronic component 16a via the connecting components 33a, 33b, 33c and 33d, respectively. The additional electronic component 16a may be operatively connected to the electronic load/grid 18a via the connecting component 17a.

According to embodiments, each of the photovoltaic material faces 30a, 30b, 30c and 30d may be configured to have any orientation, relative to a reference plane, such as the mounting plan of the power generation unit, with the orientation of each face different from the other photovoltaic material faces. The photovoltaic material faces 30a, 30b, 30c and 30d may be put together in the shape of the reversed pyramid as illustrated in FIGS. 4A and 4B. The assembly of the photovoltaic material faces 30a, 30b, 30c and 30d in the shape of three-dimensional geometry (i.e. reversed pyramid) may facilitate or enhance effective production of the photovoltaic energy. Due to the absence or significantly reduced surface area at the bottom, there may be no need to have the photovoltaic material faces at the bottom of the reversed pyramid photovoltaic structure.

According to embodiments, there may be various forms and types available for the connecting components 31a, 31b, 31c, 31d and 33a, 33b, 33c, 33d. In some embodiments, one or more of the connecting components 31a, 31b, 31c, 31d and 33a, 33b, 33c, 33d may be conventional electrical wires. In some embodiments, one or more of the connecting components 31a, 31b, 31c, 31d and 33a, 33b, 33c, 33d may be a set of transmitter(s) and receiver(s) for wireless power transmission or wireless electricity transmission. As such, the power or electric transmissions via the connecting components 31a, 31b, 31c, 31d and 33a, 33b, 33c, 33d may be wired transmissions, wireless transmissions or combination thereof.

FIGS. 4C and 4D illustrate, in a perspective view and a top view, a photovoltaic power generation apparatus with four independent photovoltaic material faces wherein two photovoltaic material faces share one power optimizer, in accordance with embodiments of the present invention.

According to embodiments, the photovoltaic power generation apparatus 400 may comprise the power generation photovoltaic structure 410 and the power optimization electronics 42a and 42b (e.g. local power optimizer), and the electronic load/grid 18a. Each of the power optimization electronics 42a and 42b may be functionally equivalent to the power optimization electronics 14a and 14b in FIG. 1. The power generation photovoltaic structure 310 may comprise the photovoltaic material faces 40a, 40b, 40c and 40d. While not shown in FIGS. 4C and 4D, the power generation photovoltaic structure 410 may further comprise cladding layer 10a and substrate layer 12a. Each of the photovoltaic material faces 40a, 40b, 40c and 40d may be functionally equivalent to the photovoltaic material faces 11a and 11b in FIG. 1. Each of the photovoltaic material faces 40a, 40b, 40c and 40d may form separate photovoltaic material face set. In some embodiments, two or more photovoltaic material faces may form one photovoltaic material face set. In some embodiments, the photovoltaic power generation apparatus 400 may further comprise the additional electronic component 16a.

According to embodiments, the power optimization electronics may be shared by plural photovoltaic material face sets. As such, power optimization for energy collected by two or more photovoltaic material faces may be performed by a single power optimizer. In some embodiments, the power optimization may be performed in a collective manner. Referring to FIGS. 4C and 4D, the power optimization electronics 42a may be shared by the photovoltaic material faces 40a and 40b; and the power optimization electronics 42c may be shared by the photovoltaic material faces 40c and 40d. In other words, the photovoltaic material faces 40a and 40b may be operatively connected to the power optimization electronic (e.g. local power optimizer) 42a via the connecting components 41a and 41b, respectively; and the photovoltaic material faces 40c and 40d may be operatively connected to the power optimization electronic (e.g. local power optimizer) 42c via the connecting components 41c and 41d, respectively. In some embodiments, the connection between the photovoltaic material faces and the power optimization electronics may be similar to the connection of multiple solar cells in series or in parallel via electrical wiring or wireless power/electricity transmission devices.

According to embodiments, each of the power optimization electronics 42a and 42c may be operatively connected to the additional electronic component 16a via the connecting components 43a and 43c, respectively. The additional electronic component 16a may be operatively connected to the electronic load/grid 18a via the connecting component 17a.

According to embodiments, each of the photovoltaic material faces 40a, 40b, 40c and 40d may be configured to have any orientation, relative to a reference plane, such as the mounting plane of the power generation unit, with the orientation of each face different for that of the other photovoltaic material faces The photovoltaic material faces 40a, 40b, 40c and 40d may be put together in the shape of the reversed pyramid as illustrated in FIGS. 4C and 4D. The assembly of the photovoltaic material faces 40a, 40b, 40c and 40d in the shape of three-dimensional geometry (i.e. reversed pyramid) may facilitate or enhance effective production of the photovoltaic energy. Due to the absence or significantly reduced surface area at the bottom, there may be no need to have the photovoltaic material faces at the bottom of the reversed pyramid photovoltaic structure.

According to embodiment, there may be various forms and types available for the connecting components 41a, 41b, 41c, 41d and 43a, 43c. In some embodiments, one or more of the connecting components 41a, 41b, 41c, 41d and 43a, 43c may be conventional electrical wires. In some embodiments, one or more of the connecting components 41a, 41b, 41c, 41d and 43a, 43c may be a set of transmitter(s) and receiver(s) for wireless power transmission or wireless electricity transmission. As such, the power or electric transmissions via the connecting components 41a, 41b, 41c, 41d and 43a, 43c may be wired transmissions, wireless transmissions or combination thereof.

According to embodiments, a photovoltaic power generation apparatus may be configured to have a photovoltaic structure with non-planar lateral surface (e.g. curved lateral surface or curved side walls). The non-planar lateral surfaces of the photovoltaic structure may be shaped in various ways. In some embodiments, the non-planar lateral surface may be configured to be shaped in a reversed cone. In some other embodiments, the non-planar lateral surfaces may be configured to be shaped in a cylinder or a truncated cone. In some embodiments, the non-lateral lateral surface may consist of one non-planar independent photovoltaic material face set. In some embodiments, the non-lateral lateral surface may consist of plural non-planar independent photovoltaic material face sets. In some embodiments, the non-lateral lateral surface may consist of mix of planar and non-planar independent photovoltaic material face sets.

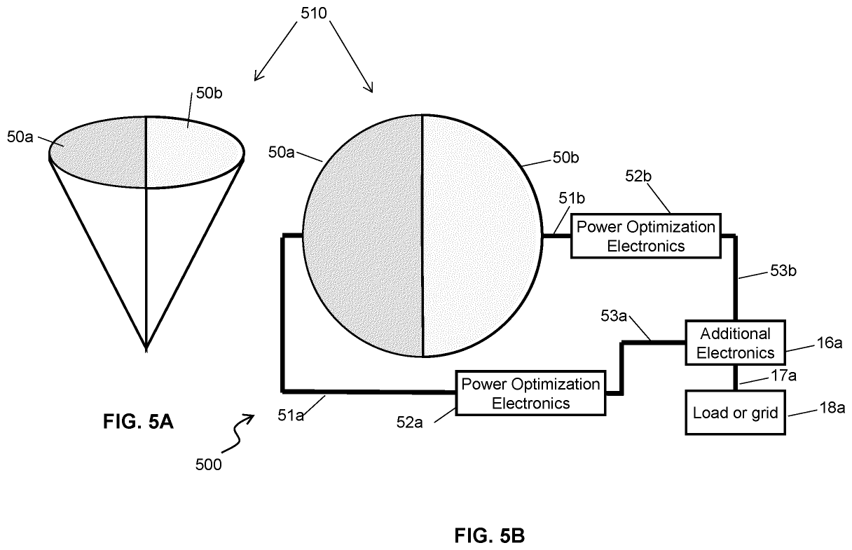

An example of the photovoltaic power generation apparatus comprising photovoltaic structure with a non-planar lateral surface is illustrated in FIGS. 5A and 5B. FIGS. 5A and 5B illustrate, in a perspective view and a top view, a photovoltaic power generation apparatus with two non-planar independent photovoltaic material faces shaped in a reversed cone, in accordance with embodiments of the present invention.

Referring to FIGS. 5A and 5B, the photovoltaic power generation apparatus 500 may comprise the power generation photovoltaic structure 510 and the power optimization electronics 52a and 52b (e.g. local power optimizer), and the electronic load/grid 18a. Each of the power optimization electronics 52a and 52b may be functionally equivalent to the power optimization electronics 14a and 14b in FIG. 1. The power generation photovoltaic structure 510 may comprise the photovoltaic material faces 50a and 50b. While not shown in FIGS. 5A and 5B, the power generation photovoltaic structure 510 may further comprise cladding layer 10a and substrate layer 12a. Each of the photovoltaic material faces 50a and 50b may be functionally equivalent to the photovoltaic material faces 11a and 11b in FIG. 1. Each of the photovoltaic material faces 50a and 50b may form separate photovoltaic material face set. In some embodiments, two or more photovoltaic material faces may form one photovoltaic material face set. In some embodiments, the photovoltaic power generation apparatus 500 may further comprise the additional electronic component 16a.

Further referring to FIGS. 5A and 5B, each of the photovoltaic material faces 50a and 50b may be operatively connected to independent power optimization electronics 52a and 52b. The photovoltaic material face 50a may be operatively connected to the power optimization electronic (e.g. local power optimizer) 52a via the connecting components 51a; and the photovoltaic material face 50b may be operatively connected to the power optimization electronic (e.g. local power optimizer) 52b via the connecting components 51b. Each of the power optimization electronics 52a and 52b may be operatively connected to the additional electronic component 16a via the connecting components 53a and 53b, respectively. The additional electronic component 16a may be operatively connected to the electronic load/grid 18a via the connecting component 17a.

According to embodiments, each of the photovoltaic material faces 50a and 50b may be configured to have a photovoltaic structure with non-planar lateral surface (e.g. curved lateral surface). The photovoltaic material faces 50a and 50b may be put together in the shape of the reversed cone as illustrated in FIGS. 5A and 5B. The assembly of the photovoltaic material faces 50a and 50b in the shape of three-dimensional curved geometry (i.e. reversed cone) may facilitate or enhance effective production of the photovoltaic energy, at least in certain circumstances. Due to the absence or significantly reduced surface area at the bottom, there may be no need to have the photovoltaic material faces at the bottom of the reversed cone photovoltaic structure.

According to embodiment, there may be various forms and types available for the connecting components 51a, 51b, 53a and 53b. In some embodiments, one or more of the connecting components 51a, 51b, 53a and 53b may be conventional electrical wires. In some embodiments, one or more of the connecting components 51a, 51b, 53a and 53b may be a set of transmitter(s) and receiver(s) for wireless power transmission or wireless electricity transmission. As such, the power or electric transmissions via the connecting components 51a, 51b, 53a and 53b may be wired transmissions, wireless transmissions or combination thereof.

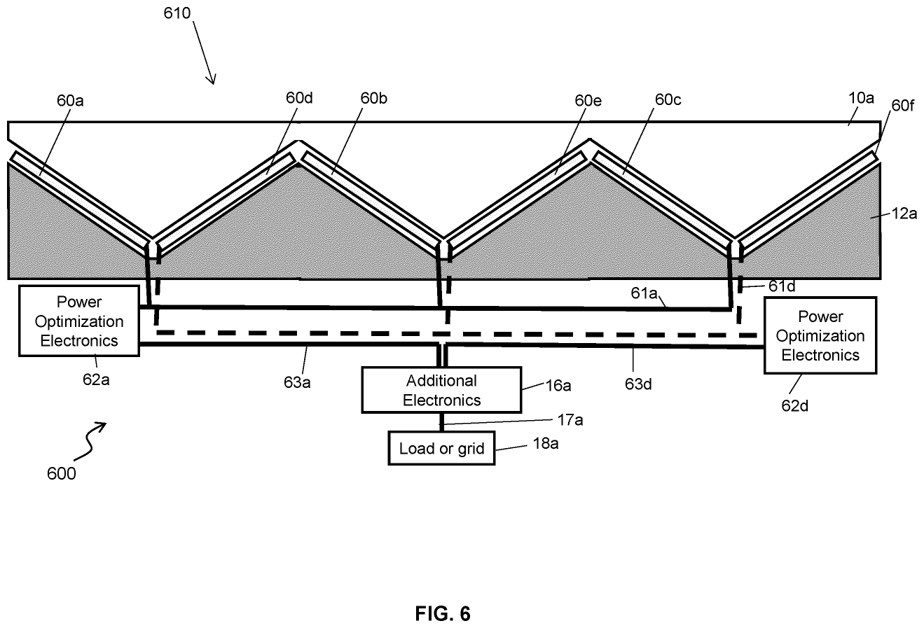

FIG. 6 illustrates, in a side view, a larger photovoltaic power generation system with two independent photovoltaic material face sets forming a three-dimensional corrugated structure, in accordance with embodiments of the present invention. According to embodiments, the photovoltaic power generation apparatus 600 may comprise the power generation photovoltaic structure 610 and the power optimization electronics 62a and 62d (e.g. local power optimizer), and the electronic load/grid 18a. The power generation photovoltaic structure 610 may comprise the photovoltaic material faces 60a, 60b, 60c, 60d, 60e, and 60f.

According to embodiments, one or more the photovoltaic material faces can form one independent photovoltaic material face set. In some embodiments, two or more photovoltaic material faces may form one photovoltaic material face set. For example, as illustrated in FIG. 6, the photovoltaic material faces 60a, 60b and 60c may form one photovoltaic material face set and the photovoltaic material faces 60d, 60e and 60f may form another photovoltaic material face set. However, in some other embodiments, each photovoltaic material face set may comprise only one photovoltaic material face, as illustrated in FIGS. 1 and 3 to 5.

According to embodiments, the power generation photovoltaic structure 610 may further comprise cladding layer 10a and substrate layer 12a. Each of the power optimization electronics 62a and 62d may be functionally equivalent to the power optimization electronics 14a and 14b in FIG. 1. Each of the photovoltaic material faces 60a, 60b, 60c, 60d, 60e, and 60f may be functionally equivalent to the photovoltaic material faces 11a and 11b in FIG. 1. In some embodiments, the photovoltaic power generation apparatus 600 may further comprise the additional electronic component 16a.

Referring to FIG. 6, the photovoltaic material faces 60a, 60b, 60c, 60d, 60e and 60f may be operatively connected to independent power optimization electronics 52a and 52b. The photovoltaic material faces in the same photovoltaic material face set may be connected to same power optimization electronic. The photovoltaic material faces 60a, 60b and 60c may be operatively connected to the power optimization electronic (e.g. local power optimizer) 62a via the connecting components 61a; and the photovoltaic material face 60d, 60e and 60f may be operatively connected to the power optimization electronic (e.g. local power optimizer) 62d via the connecting components 61d. Each of the power optimization electronics 62a and 62d may be operatively connected to the additional electronic component 16a via the connecting components 63a and 63d, respectively. The additional electronic component 16a may be operatively connected to the electronic load/grid 18a via the connecting component 17a.

According to embodiments, the cladding layer 10a may be disposed on the photovoltaic material faces 60a, 60b, 60c, 60d, 60e and 60f which may be disposed on the substrate layer 12a. While the cladding layer 10a is proximate to the photovoltaic material faces, the cladding layer 10a and the photovoltaic material faces 60a, 60b, 60c, 60d, 60e and 60f may not be in direct contact with each other and thin gap may exist therebetween. Similarly, while the substrate layer 12a is proximate to the photovoltaic material faces 11a and 11b, the substrate layer 12a and the photovoltaic material faces 60a, 60b, 60c, 60d, 60e and 60f may not be in direct contact with each other and thin gap may exist therebetween. However, in some embodiments, at least part of the cladding layer 10a may be in direct contact with the photovoltaic material faces 60a, 60b, 60c, 60d, 60e and 60f. Similarly, in some embodiments, at least part of the substrate layer 12a may be in direct contact with the photovoltaic material faces 60a, 60b, 60c, 60d, 60e and 60f. The substrate layer 12a may provide some space for the connection between the photovoltaic material faces (60a, 60b, 60c, 60d, 60e and 60f) and the power optimization electronics (62a, 62d). In some embodiments, at least part of the cladding layer 10a and the substrate layer 12a may be in contact with each other.

According to embodiments, each of the photovoltaic material faces 60a, 60b, 60c, 60d, 60e and 60f may be configured to have any orientation, relative to a reference plane, such as the mounting plane of the power generation unit, with each orientation different from that of the other photovoltaic material faces. The photovoltaic material faces 60a, 60b, 60c, 60d, 60e and 60f may be configured to optimize the photovoltaic energy production. Also, due to the absence or significantly reduced surface area at the bottom, there may be no need to have the photovoltaic material faces at the bottom of the three-dimensional photovoltaic structure.

According to embodiments, there may be various forms and types available for the connecting components 61a, 61d, 63a and 63d. In some embodiments, one or more of the connecting components 61a, 61d, 63a and 63d may be conventional electrical wires. In some embodiments, one or more of the connecting components 61a, 61d, 63a and 63d may be a set of transmitter(s) and receiver(s) for wireless power transmission or wireless electricity transmission. As such, the power or electric transmissions via the connecting components 61a, 61d, 63a and 63d may be wired transmissions, wireless transmissions or combination thereof.

According to various embodiments of the present invention, the photovoltaic power generation apparatus may be used in a wide range of forms. In one example, the photovoltaic structure, which may comprise an array of the photovoltaic material faces, may be installed or deployed on roadways replacing asphalt roads so that electricity can be generated for local consumption (e.g. energy for local houses, businesses and electric cars). In another example, the photovoltaic structure may be deployed on top of the houses or building as a photovoltaic roof generating electrical energy from sunlight.

Although the present invention has been described with reference to specific features and embodiments thereof, it is evident that various modifications and combinations can be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

In particular, it is within the scope of the technology to provide a computer program product or program element, or a program storage or memory device for storing signals readable by a processor, for controlling the operation of a power optimizer.

Acts associated with the method described herein can be implemented as coded instructions in a computer program product. In other words, the computer program product is a computer-readable medium upon which software code is recorded to execute the power optimization when the computer program product is loaded into memory and executed on the microprocessor.

Acts associated with methods described herein can be implemented as coded instructions in plural computer program products. For example, a first portion of the method may be performed using one computing device, and a second portion of the method may be performed using another computing device. In this case, each computer program product is a computer-readable medium upon which software code is recorded to execute appropriate portions of the method when a computer program product is loaded into memory and executed on the microprocessor of a computing device. In addition, each step, or a file or object or the like implementing each said step, may be executed by special purpose hardware or a circuit module designed for that purpose.

It is obvious that the foregoing embodiments of the invention are examples and can be varied in many ways. Such present or future variations are not to be regarded as a departure from the spirit and scope of the invention, and all such modifications as would be obvious to one skilled in the art are intended to be included within the scope of the following claims.

We claim:

1. A photovoltaic power generation apparatus comprising:
one or more three-dimensional photovoltaic structures generating electrical power, each photovoltaic structure including:
two or more of photovoltaic material face sets, each photovoltaic material face set including:
one or more photovoltaic material faces;
a cladding layer disposed on the one or more photovoltaic material faces, and
a substrate layer upon which the one or more photovoltaic material faces are disposed;
wherein the two or more photovoltaic material face sets are oriented at angles at least in part different from each other; and
one or more power optimizers, the one or more power optimizers operatively connected to the two or more of photovoltaic material face sets, wherein operation of each of the two or more photovoltaic material face sets are independently controlled by the one or more power optimizers.

2. The apparatus according to claim 1, wherein the one or more power optimizers are configured as an electronic component including a processor and machine executable instructions which when executed by the processor perform power optimization, or the one or more power optimizers are configured as integrated circuits.

3. (canceled)

4. The apparatus according to claim 1, wherein the one or more power optimizers are configured to perform optimization using one or more of: maximum power point tracking, a variable inductor, curve fitting, incremental resistance, incremental conductance, parasitic capacitance, forced oscillation, ripple correlation, current sweep and fuzzy logic optimization.

5. The apparatus according to claim 2, wherein the one or more power optimizers are configured perform maximum power point tracking.

6. The apparatus according to claim 1, wherein the one or more photovoltaic material faces associated with a first photovoltaic material face set are oriented in a first direction and the one or more photovoltaic material faces associated with a second photovoltaic material face set are oriented in a second direction, the first direction different from the second direction.

7. The apparatus according to claim 6, wherein a first power optimizer is operatively coupled to the one or more photovoltaic material faces associated with a first photovoltaic material face set and a second power optimizer is operatively coupled to the one or more photovoltaic material faces associated with the second photovoltaic material face set.

8. The apparatus according to claim 7, wherein the first power optimizer and the second power optimizer are independently operative.

9. The apparatus according to claim 1, wherein the one or more power optimizers are operatively connected to supplementary micro-inverter configured to provide additional power optimization.

10. The apparatus according to claim 1, wherein the one or more power optimizers are operatively connected to one or more of a DC-to-DC converter, a DC-to-AC converter, a battery storage system, a power grid and a load.

11. The apparatus according to claim 1, wherein at least one of the one or more photovoltaic material faces are curvilinear.

12. A three-dimensional photovoltaic structure for generating electrical power, the structure comprising:
two or more of photovoltaic material face sets, each photovoltaic material face set including:
one or more photovoltaic material faces, each photovoltaic material face being operatively connected to a power optimizer;
a cladding layer disposed on the one or more photovoltaic material faces; and
a substrate layer upon which the one or more photovoltaic material faces are disposed;
wherein the two or more photovoltaic material face sets are oriented at angles at least in part different from each other.

13. The structure according to claim 12, wherein at least one of the power optimizers are configured as an electronic component including a processor and machine executable instructions which when executed by the processor perform power optimization, or at least one of the power optimizers are configured as integrated circuits.

14. (canceled)

15. The structure according to claim 12, wherein at least one of the power optimizers are configured to perform optimization using one or more of: maximum power point tracking, a variable inductor, curve fitting, incremental resistance, incremental conductance, parasitic capacitance, forced oscillation, ripple correlation, current sweep and fuzzy logic optimization.

16. The structure according to claim 13, wherein at least one of the power optimizers are configured perform maximum power point tracking.

17. The structure according to claim 12, wherein the one or more photovoltaic material faces associated with a first photovoltaic material face set are oriented in a first direction and the one or more photovoltaic material faces associated with a second photovoltaic material face set are oriented in a second direction, the first direction different from the second direction.

18. The structure according to claim 17, wherein a first power optimizer is operatively coupled to the one or more photovoltaic material faces associated with a first photovoltaic material face set and a second power optimizer is operatively coupled to the one or more photovoltaic material faces associated with the second photovoltaic material face set.

19. The structure according to claim 18, wherein the first power optimizer and the second power optimizer are independently operative.

20. The structure according to claim 12, wherein the one or more power optimizers are operatively connected to supplementary micro-inverter configured to provide additional power optimization.

21. The structure according to claim 12, wherein the one or more power optimizers are operatively connected to one or more of a DC-to-DC converter, a DC-to-AC converter, a battery storage system, a power grid and a load.

22. The structure according to claim 12, wherein at least one of the one or more photovoltaic material faces are curvilinear.
